(19) United States
(12) Patent Application Publication
(10) Pub. No.: US 2024/0290882 A1
(43) Pub. Date: Aug. 29, 2024

(54) SEMICONDUCTOR DEVICE HAVING SILICON PLUGS FOR TRENCH AND/OR MESA SEGMENTATION

(71) Applicant: Infineon Technologies Austria AG, Villach (AT)

(72) Inventors: Annett Winzer, Dresden (DE); Lars Mueller-Meskamp, Dresden (DE); Ralf Rudolf, Dresden (DE); Tom Peterhaensel, Dresden (DE); Birgit von Ehrenwall, Radebeul (DE); Frido Erler, Dresden (DE); Dirk Manger, Dresden (DE)

(21) Appl. No.: 18/113,351

(22) Filed: Feb. 23, 2023

(51) Int. Cl. H01L 29/78; H01L 21/762

(52) U.S. Cl. CPC H01L 29/7816; H01L 21/76224

(57) ABSTRACT

A semiconductor device includes: a silicon layer having a frontside and an electrically insulated backside; a first trench extending through the silicon layer from the frontside to the electrically insulated backside and laterally isolating a first region of the silicon layer; an electrically conductive material in the first trench; a dielectric material separating the electrically conductive material from silicon material of the silicon layer; and a plurality of silicon plugs laterally surrounded by the dielectric material and dividing the electrically conductive material into a plurality of separate segments in the first trench. Additional embodiments of semiconductor devices and methods for manufacturing the semiconductor devices are also described.

### BACKGROUND

For SOI (silicon-on-insulator) and SOI-like technologies, deep trench isolation is needed with an insulating liner and a seamless or nearly void-free conductive fill such as doped or undoped polysilicon. For SOI-like technologies where an SOI structure is formed by backside thinning and isolation post device fabrication, the deep trench isolation enables backside grinding into the fill trenches without wafer fracture and the subsequent backside oxide deposition. Conventionally, for such a deep trench isolation in SOI and SOI-like technologies, different voltage domains are separated laterally by enclosed deep trench rings. Deep isolation trench crossings are not permitted because of the risk of electrical connection (short) of the trench conductive fill and/or silicon mesas between stacked trench rings and resulting failure of the deep trench isolation between different voltage domains. Furthermore, conventional deep trench isolation rings do not allow for asymmetrical and/or stacked high-voltage devices and results in a greater high-voltage device area.

### SUMMARY

According to an embodiment of a semiconductor device, the semiconductor device comprises: a silicon layer having a frontside and an electrically insulated backside; a first trench extending through the silicon layer from the frontside to the electrically insulated backside and laterally isolating a first region of the silicon layer; an electrically conductive material in the first trench; a dielectric material separating the electrically conductive material from silicon material of the silicon layer; and a plurality of silicon plugs laterally surrounded by the dielectric material and dividing the electrically conductive material into a plurality of separate segments in the first trench.

According to another embodiment of a semiconductor device, the semiconductor device comprises: a silicon layer having a frontside and an electrically insulated backside; a plurality of trenches extending through the silicon layer from the frontside to the electrically insulated backside and laterally isolating a plurality of regions of the silicon layer; an electrically conductive material in trenches; a dielectric material separating the electrically conductive material from silicon material of the silicon layer; a first silicon mesa between adjacent ones of the trenches in a first lateral direction; a second silicon mesa between adjacent ones of the trenches in a second lateral direction that is transverse to the first lateral direction, wherein the first and second silicon mesas intersect one another; and in an area where the first and second silicon mesas intersect one another, a silicon plug or silicon mesa laterally surrounded by the dielectric material and separating the first and second silicon mesas from one another.

According to another embodiment of a semiconductor device, the semiconductor device comprises: a silicon layer having a frontside and an electrically insulated backside; a plurality of trenches extending through the silicon layer from the frontside to the electrically insulated backside and laterally isolating a plurality of regions of the silicon layer, wherein a middle one of the trenches in a first lateral direction intersects a middle one of the trenches in a second lateral direction that is transverse to the first lateral direction; an electrically conductive material in the trenches; a dielectric material separating the electrically conductive material from silicon material of the silicon layer; a silicon mesa between adjacent ones of the trenches in the first lateral direction and between adjacent ones of the trenches in the second lateral direction; and a silicon plug laterally surrounded by the dielectric material and interrupting the electrically conductive material where the middle trench in the first lateral direction intersects the middle trench in the second lateral direction.

According to another embodiment of a semiconductor device, the semiconductor device comprises: a silicon layer having a frontside and an electrically insulated backside; a first pair of trenches extending through the silicon layer from the frontside to the electrically insulated backside and segmenting the silicon layer in a first lateral direction; a second pair of trenches extending through the silicon layer from the frontside to the electrically insulated backside and segmenting the silicon layer in a second lateral direction that is transverse to the first lateral direction; an electrically conductive material in the first pair of trenches and the second pair of trenches; a dielectric material separating the electrically conductive material from silicon material of the silicon layer; a first silicon mesa interposed between the trenches of the first pair; a second silicon mesa interposed between the trenches of the second pair; and in an area where the first pair of trenches and the second pair of trenches intersect one another, a plurality of silicon plugs laterally surrounded by the dielectric material and dividing the electrically conductive material into a plurality of separate segments in the trenches.

According to an embodiment of a method for manufacturing a semiconductor device, the method comprises: providing a silicon layer having a frontside and an electrically insulated backside; and forming a first trench structure that extends through the silicon layer from the frontside to the electrically insulated backside and that laterally isolates a first region of the silicon layer, wherein forming the first trench structure comprises: forming an electrically conductive material in the first trench; forming a dielectric material that separates the electrically conductive material from silicon material of the silicon layer; and forming a plurality of silicon plugs laterally surrounded by the dielectric material and that divide the electrically conductive material into a plurality of separate segments in the first trench.

Those skilled in the art will recognize additional features and advantages upon reading the following detailed description, and upon viewing the accompanying drawings.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates a cross-sectional view of part of a semiconductor device, according to an embodiment.

FIGS. 2A through 2C illustrate partial top plan views of the semiconductor device in a region of one or more of silicon plugs, according to further embodiments.

FIG. 3A illustrates a partial top plan view of the semiconductor device, according to another embodiment.

FIG. 3B illustrates a cross-sectional view along the line labelled A-A′ in FIG. 3A.

FIGS. 4 through 11 illustrate respective partial top plan views of the semiconductor device, according to additional embodiments.

### DETAILED DESCRIPTION

The embodiments described enable deep trench isolation crossings and other deep trench isolation configurations such as segmented isolation trenches by using dielectrically insulated silicon plugs. The silicon plugs enable different voltage domains within the same silicon layer, without sacrificing extensive die (chip) area compared to conventional deep trench isolation rings only without crossings. Each silicon plug may be embedded in a trench dielectric liner or positioned within trench or mesa crossings, yielding a CD (critical dimension) reduction where the trench is filled with an insulating liner only. At the silicon plug, the insulation capability is approximately doubled. Thus, no dielectric breakdown weakness is created. Trench pinching provided by the silicon plugs enables edge termination by deep trenches for high-voltage devices. A high voltage drop along a trench may be interrupted from high potential (e.g., drain) to low potential (e.g., source) by using one or more the silicon plugs. Asymmetrical devices may be enabled by using the silicon plugs, since the conductive fill within trench lines can be disconnected by one or more silicon plugs. Moreover, no additional high-voltage routing is needed. The silicon plugs described herein enable segmentation of the conductive trench fill (e.g., doped or undoped polysilicon) which may be used as capacitor plates. Hence, multi-channel capacitive coupling may be provided by using the silicon plugs.

Described next, with reference to the figures, are embodiments of semiconductor devices that use the silicon plugs and related methods of manufacturing.

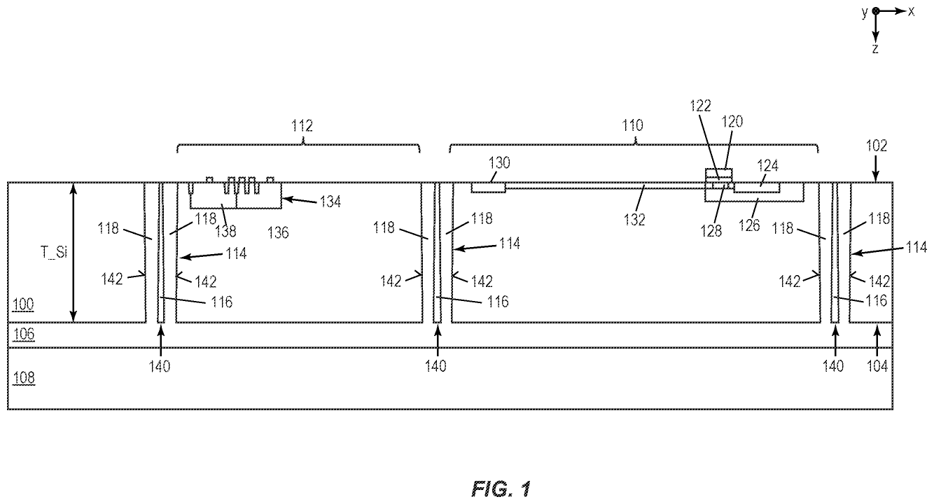

FIG. 1 illustrates a cross-sectional view of part of a semiconductor device, according to an embodiment. The semiconductor device includes a silicon layer 100 having a frontside 102 and an electrically insulated backside 104. The silicon layer 100 may be doped n-type or p-type. A dielectric material 106 covers the backside 104 of the silicon layer 100, making the backside 104 electrically insulated.

The dielectric material 106 covering the backside 104 of the silicon layer 100 may be a deposited oxide having a thickness in a range of 0.8 μm (microns) to μ35 um, for example. In another example, the dielectric material 106 may be an electrically insulative die attach film applied to the backside 104 of the silicon layer 100. Still other types of electrically insulative material or material stacks may be used as the dielectric material 106 that covers the backside 104 of the silicon layer 100. One or more additional structures 108 such as one or more metallization layers 124 like Cu (copper), Al (aluminum), AlCu, etc., barrier layer, adhesion promotion layer, polysilicon, mold compound, die attach film, Si carrier, lead frame, adhesive, circuit board, interposer, another die, etc. may be applied to the dielectric material 106 covering the backside 104 of the silicon layer 100.

A first region 110 and a second region 112 are formed in the silicon layer 100 and laterally spaced apart from one another by at least one trench 114. The first region 110 may include one or more isolated high voltage (e.g., 20V or higher) islands and the low voltage region 112 may include one or more isolated low voltage (e.g., less than 20V) islands.

The trench 114 extends through the silicon layer 100 from the frontside 102 to the electrically insulated backside 104 and laterally isolates the first and second regions 110, 112 of the silicon layer 100. An electrically conductive material 116 such as doped or undoped polysilicon and/or a metal or metal stack is disposed in the trench 114. A dielectric material 118 separates the electrically conductive material 116 in the trench 114 from the silicon material of the silicon layer 100. The dielectric material 118 may be SiOx, SiN, HfOx, AlxOy (e.g., Al₂O₃), TEOS (tetraethoxysilane), etc. or a layer stack of two or more of these or similar dielectric materials.

In FIG. 1, an LDMOS device is formed in the first region 110 of the silicon layer 100. The LDMOS device includes a planar gate electrode 120 separated from the frontside 102 of the silicon layer 100 by a gate dielectric 122, a source region 124 disposed in a body region 126 of the opposite conductivity type and which includes a channel region 128 controlled by the gate electrode 120, and a drain region 130 disposed at the same side of the semiconductor silicon layer 100 as the source region 124 and laterally separated from the channel region 128 by a drift zone 132 of the same conductivity type as the source and drain regions 124, 130. The second region 112 may include logic and/or power device features 134 formed in different voltage islands 136, 138. These are just a few examples of the first and second regions 110, 112 of the silicon layer 100 and should not be considered limiting.

The trenches 114 may adjoin the first region 110, adjoin the second region 112, or laterally separate the first and second regions 110, 112 from one another, for example. The electrically conductive material 116 in each trench 114 may be electrically connected to a potential applied to a region of the first voltage region 110, a potential applied to a region of the second region 112, a different potential or signal, or may be floating.

In FIG. 1, the electrically conductive material 116 in each trench 114 terminates at the electrically insulated backside 104 of the silicon layer 100 at the bottom 140 of the trench 114 and is laterally separated from the silicon layer 100 by the dielectric material 118 that lines the sidewall(s) 142 of the trench 114. In the case of a stripe-shaped trench, the trenches 114 have two opposing sidewalls 142 lined by the dielectric material 118. The term ‘stripe-shaped’ as used herein means a structure having a longest linear dimension in a direction (y direction in FIG. 1) transverse to the depth-wise direction (z direction in FIG. 1) of the silicon layer 100.

In one embodiment, the thickness T_Si of the silicon layer 100 is in a range of 10 μm to 200 μm between the frontside 102 and the electrically insulated backside 104 of the silicon layer 100. The silicon layer 100 with the electrically insulated backside 104 may be realized by forming one or more devices such as a power diode(s), high voltage transistor(s), a gate driver for a power transistor, etc. in a bulk silicon wafer or in one or more epitaxial layers grown on a bulk silicon wafer, and then grinding the backside of the bulk silicon wafer to the final SOI thickness T_Si.

For example, in FIG. 1, the backside wafer grinding may stop on the electrically conductive material 116 in the trenches 114 that laterally isolates the first and second regions 110, 112 of the silicon layer 100. The thinned wafer backside is then covered by the dielectric material 106 to yield the electrically insulated backside 104 of the silicon layer 100. The resulting silicon layer 100 is thicker (e.g., T_Si=10 μm to 200 μm) than typical SOI device layers which usually have a thickness in the nanometer (nm) range. The silicon layer 100 instead may be a standard SOI device layer formed by SIMOX (separation by implantation of oxygen, wafer bonding, etc. and having a thickness T_Si of less than 10 μm.

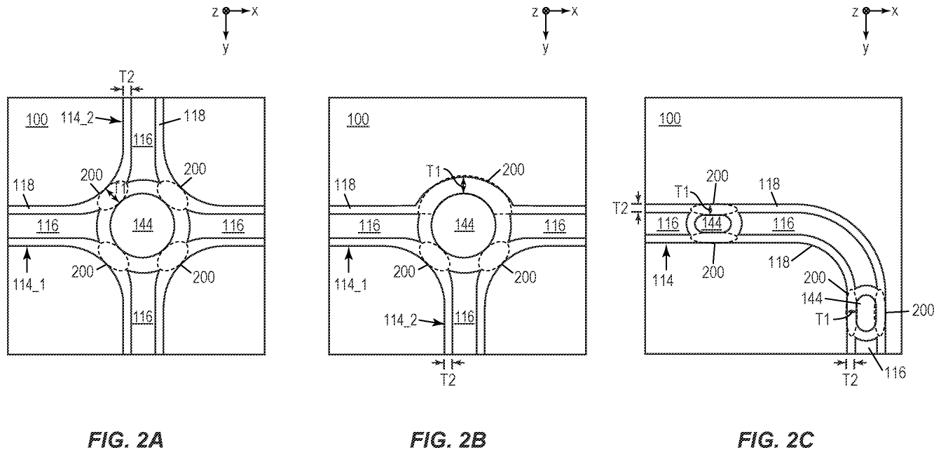

The semiconductor device illustrated in FIG. 1 also includes silicon plugs 144 that are laterally surrounded by the trench dielectric material 118 and divide the electrically conductive material 116 in the trenches 114 into separate segments 116_1, . . . , 116_n in the trenches 114. The silicon plugs 144 are out of view in FIG. 1. FIGS. 2A through 2C illustrate partial top plan views of the semiconductor device in the region of one or more of the silicon plugs 144. The silicon plugs 144 are shown as having a circular cross-sectional shape in the horizontal plane (x-y plane in FIGS. 2A through 2C). This is just an example. In general, the plugs 144 may have any curvilinear or rectilinear cross-sectional shape in the horizontal plane (x-y plane in FIGS. 2A through 2C) permitted using lithographic processes.

In FIG. 2A, first and second trenches 114_1, 114_2 intersect one another in two different lateral directions (x and y directions in FIG. 2A). A silicon plug 114 interrupts the electrically conductive material 116 where the first and second trenches 114_1, 114_2 intersect one another. In a lateral direction (x or y direction in FIG. 2A), the average thickness T_1 of the dielectric material 118 around the silicon plug 144 may be greater than the average thickness T_2 of the dielectric material 118 between the silicon material of the silicon layer 100 and the electrically conductive material 116 in the trenches 114_1, 114_2.

A local CD reduction of the mask (not shown) used to etch the intersecting trenches 114_1, 114_2 into the silicon layer 100 may be used in regions 200 where the electrically conductive material 116 in the trenches 114_1, 114_2 is to be interrupted. The intersecting trenches 114_1, 114_2 completely fill during a subsequent dielectric deposition process (e.g., TEOS) in the regions 200 of reduced CD. Accordingly, the trench dielectric material 118 is thicker (T1>T2) in the regions 200 of reduced CD compared to the regions of the trenches 114_1, 114_2 which include the electrically conductive material 116. The regions of the silicon layer 100 where the silicon plugs 114 are to be formed may be masked (protected) during the trench etching process to define the silicon plugs 114 during the trench etching process. For example, the surroundings of the silicon plugs 144 may be etched in a first step and the trenches 114 etched in a second step after the first step, with the silicon plugs 144 being covered by a mask during the second etch step. In another example, the surroundings of the silicon plugs 144 and the trenches 114 may be etched in a single step.

In FIG. 2B, first and second trenches 114_1, 114_2 merge with one another at a T-shaped crossing. A silicon plug 114 interrupts the electrically conductive material 116 where the first and second trenches 114_1, 114_2 merge with one another. As explained above in connection with FIG. 2A, the silicon plug 114 may be defined by masking during the trench etching process and a local CD reduction of the mask (not shown) used to etch the merging trenches 114_1, 114_2 into the silicon layer 100 may be used in regions 200 where the electrically conductive material 116 in the trenches 114_1, 114_2 is to be interrupted such that the trench dielectric material 118 is thicker (T1>T2) in the regions 200 of reduced CD compared to the regions of the trenches 114_1, 114_2 which include the electrically conductive material 116.

In FIG. 2C, the electrically conductive material 116 in a single trench 114 is interrupted at least once by a respective silicon plug 114, e.g., near a corner region of the trench 114. As explained above in connection with FIG. 2A, the silicon plugs 114 may be defined by masking during the trench etching process and a local CD reduction of the mask (not shown) used to etch the trench 114 into the silicon layer 100 may be used in regions 200 where the electrically conductive material 116 in the trenches 114_1, 114_2 is to be interrupted such that the trench dielectric material 118 is thicker (T1>T2) in the regions 200 of reduced CD compared to the regions of the trenches 114_1, 114_2 which include the electrically conductive material 116.

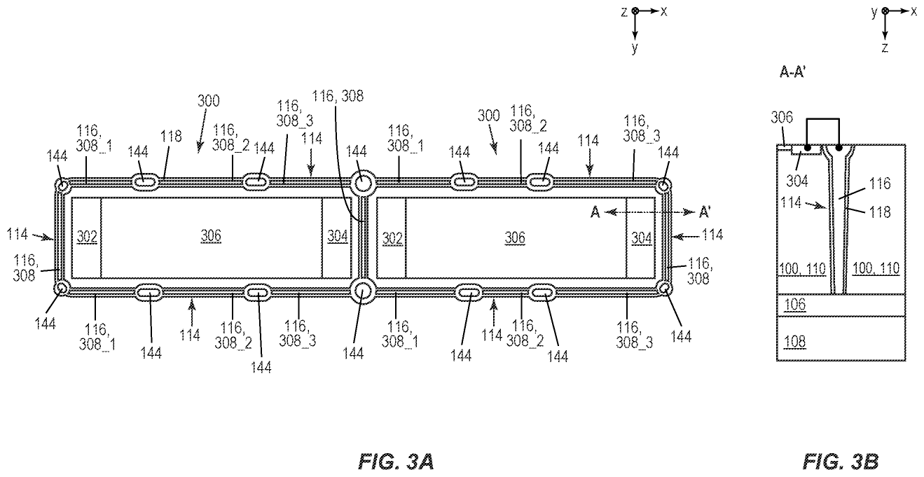

FIG. 3A illustrates a partial top plan view of the first region 110 of the silicon layer 100 and FIG. 3B illustrates a corresponding cross-sectional view along the line labelled A-A′ in FIG. 3A, according to an embodiment. In FIGS. 3A and 3B, the first region 110 of the silicon layer 102 includes at least one transistor device 300 each having a source region 302 laterally separated from a drain region 304 by a drift region 306. According to this embodiment, silicon plugs 144 divide the electrically conductive material 116 in each trench 114 into separate segments 308 between the source region 302 and the drain region 304 of each transistor device 300 such that the separate segments 308 are at different potentials when the respective transistor device is off and a high voltage is applied to the drain region 304 and a low potential to the source region 302.

Two transistor devices 300 are shown back-to-back in FIG. 3A. In one embodiment, the two transistor devices 300 are cascaded devices. For example, the two transistor devices 300 may be 100V devices cascaded in series to yield a 200V device where the source and drain regions 302, 304 of the cascaded devices 300 are at the same potential, e.g., by using metal routing to connect the source and drain regions 302, 304 of the cascaded devices 300 or by eliminating the trench 114 that separates the source and drain regions 302, 304 of the cascaded devices 300. More than two transistor devices 300 may be cascaded in this manner. Asymmetrical devices also may be realized, since the electrically conductive material 116 in the trenches 114 may be disconnected by the silicon plugs 144.

If the electrically conductive material 116 in the trench 114 that surrounds each transistor device 300 is not disrupted between the source region 302 and the drain region 304, the electrically conductive material 116 will capacitively couple to both source and drain potentials and float to an intermediate potential which is present along the entire side of the trench 114. If the floating potential is high enough, breakdown of the trench dielectric material 118 will occur. By disrupting the electrically conductive material 116 in the corresponding trench 114 using the silicon plugs 144, a better controlled potential drop occurs along the trench 114 between the source and drain regions 302, 304. For example, the leftmost electrically conductive trench segment 308_1 is around source potential, the center electrically conductive trench segment 308_2 is at an intermediate potential, and the rightmost electrically conductive trench segment 308_3 is around drain potential. The silicon plugs 144 and the electrically conductive trench segments 308 may be floating or connected to a potential. For example, the leftmost electrically conductive trench segment 308_1 may be connected to source potential, the rightmost electrically conductive trench segment 308_3 may be connected to drain potential, and the center electrically conductive trench segment 308_2 may be floating.

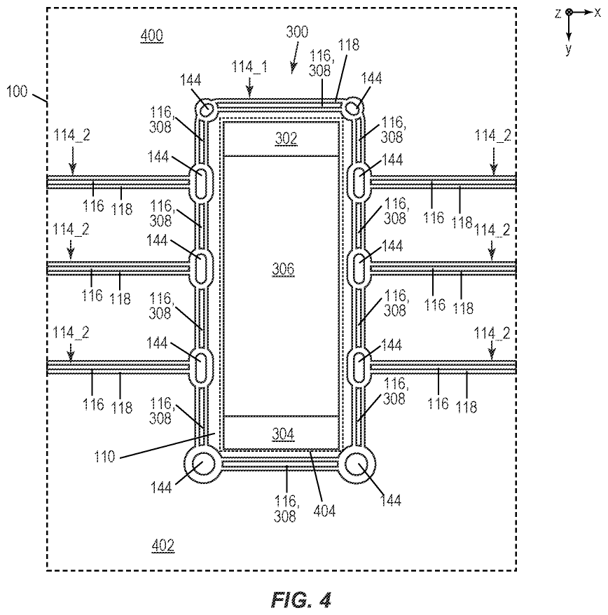

FIG. 4 illustrates a partial top plan view of the silicon layer 100, according to an embodiment. In FIG. 4, second trenches 114_2 extend through the silicon layer 100 from the frontside 102 to the electrically insulated backside 104 and merge with the trench 114_1 that surrounds the transistor device 300. The second trenches 114_2 laterally isolate a first additional region 400 of the silicon layer 100 from a second additional region 402 of the silicon layer 100. In one embodiment, the first additional region 400 supports a higher voltage domain than the second additional region 402. For example, the first additional region 400 may support a voltage domain of 200V or higher and the second additional region 402 may support a voltage domain of less than 200V.

The transistor 300 formed in the first region 110 of the silicon layer 100 may be part of a level shifter device 404 that provides voltage level shifting between the first and second additional regions 400, 402. Silicon plugs 144 interrupt the electrically conductive material 116 where the second trenches 114_2 merge with the trench 114_1 that defines first region 110 of the silicon layer 100.

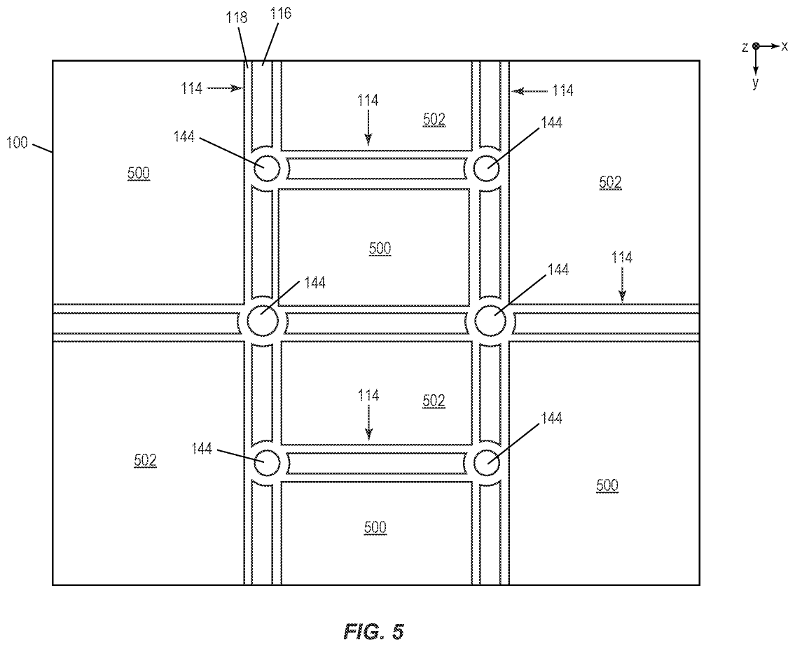

FIG. 5 illustrates a partial top plan view of the silicon layer 100, according to another embodiment. In FIG. 5, silicon plugs 144 interrupt the electrically conductive material 116 at each location where trenches 114 merge with or intersect one another. Such a configuration allows for segmentation of the silicon layer 100 into at least two different voltage domains 500, 502 that are separated from one another.

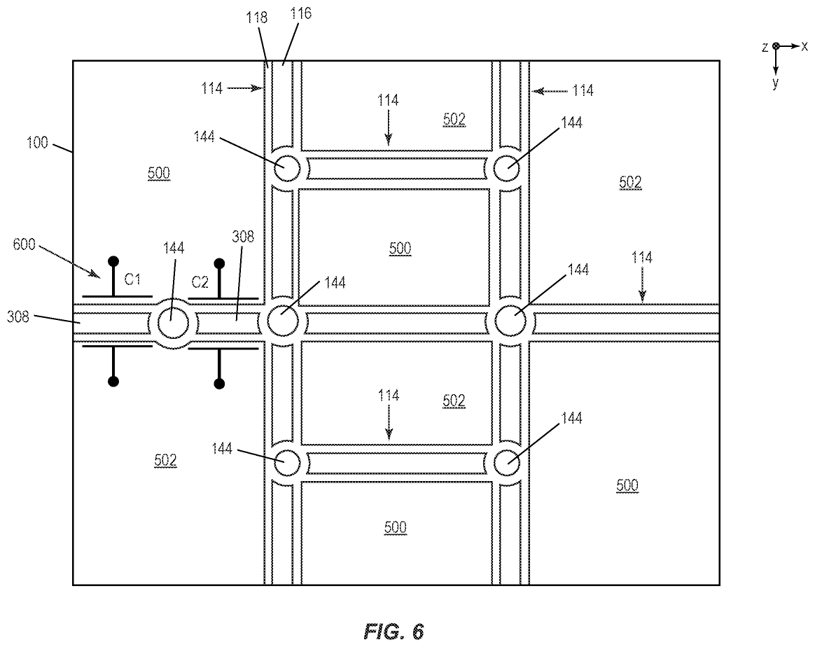

FIG. 6 illustrates a partial top plan view of the silicon layer 100, according to another embodiment. The embodiment illustrated in FIG. 6 is similar to the embodiment illustrated in FIG. 5. In FIG. 6, however, a capacitive coupler 600 is formed between regions of the silicon layer that support different voltage domains 500, 502. The capacitive coupler 600 is formed by using at least one silicon plug 144 to divide the electrically conductive material 116 in the corresponding trench 114 into at least two separate segments 308 between the regions of the silicon layer 100 that support different voltage domains 500, 502.

The silicon plugs 144 enable the capacitive coupler 600, by using trench capacitance to transmit a signal. Multiple trenches may be used and segmented using the silicon plugs 144 to form more than one capacitive coupler 600. At least two capacitances C1, C2 may be used to enable differential signalling. The electrically conductive segments 308 realized by employing the silicon plugs 144 can be used electrodes. If the silicon region adjoining the corresponding trench 114 is thin enough, the narrow silicon region may be low doped to complete the capacitive coupler 600. Each capacitive coupler 600 may be driven and sensed independently, which can be done inside the respective voltage domain 500, 502, e.g., by a gate driver with separate isolation.

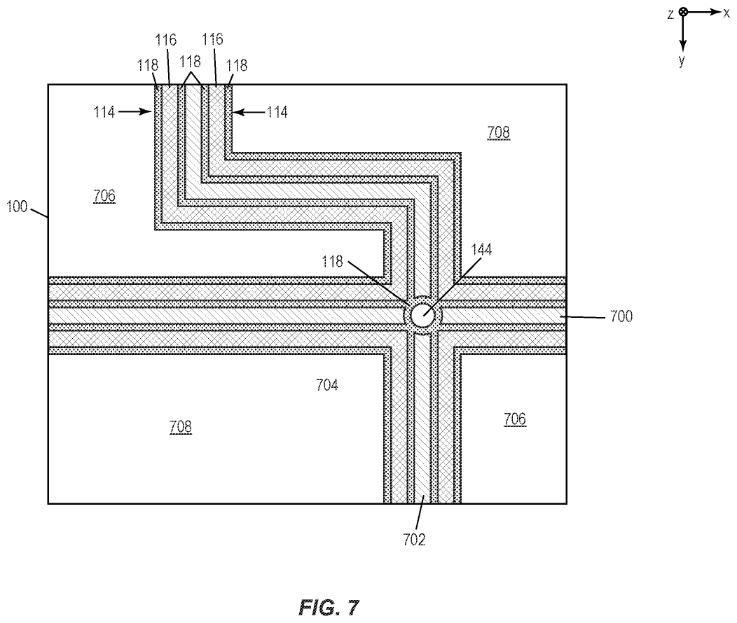

FIG. 7 illustrates a partial top plan view of the silicon layer 100, according to another embodiment. In FIG. 7, the semiconductor device has a first silicon mesa 700 between (delimited by) adjacent ones of the trenches 114 in a first lateral direction (x direction in FIG. 7) and a second silicon mesa 702 between (delimited by) adjacent ones of the trenches 114 in a second lateral direction (y direction in FIG. 7) that is transverse to the first lateral direction. The first and second silicon mesas 700, 702 intersect one another.

In an area 704 where the first and second silicon mesas 700, 702 intersect one another, a silicon plug 144 laterally surrounded by the trench dielectric material 118 separates the first and second silicon mesas 700, 702 from one another. Deep isolated mesa crossings 704 enable different voltage domains 706, 708 to be placed next to each other without sacrificing die (chip) area.

In one embodiment, a first subset 706 of the laterally isolated regions 706, 708 of the silicon layer 100 supports a first voltage domain and a second subset 708 of the laterally isolated regions 706, 708 of the silicon layer 100 supports a second voltage domain different than the first voltage domain. In the corner area 704 where one or more of the laterally isolated regions 706 of the first voltage domain adjoin one or more of the laterally isolated regions 708 of the second voltage domain, the silicon plug 144 separates the first and second silicon mesas 700, 702 from one another.

As explained above in connection with FIGS. 2A through 2C, the silicon plug 114 may be defined by masking during the trench etching process and a local CD reduction of the mask (not shown) used to etch the trenches 114 into the silicon layer 100 may be used in areas 704 where the first and second silicon mesas 700, 702 intersect one another such that the trench dielectric material 118 is thicker in the areas 704 of reduced CD compared to the regions of the trenches 114 which include the electrically conductive material 116.

In a lateral direction (x or y direction in FIG. 7), the average thickness of the trench dielectric material 118 around the silicon plug 144 may be greater than the average thickness of the trench dielectric material 118 between the silicon material of the respective mesa 700, 702 and the electrically conductive material 116 in the adjoining trench 114. According to this embodiment, the silicon plug 144 is positioned within a mesa crossing 704 to yield a CD reduction and thus thicker dielectric material 118 at the mesa crossing 704.

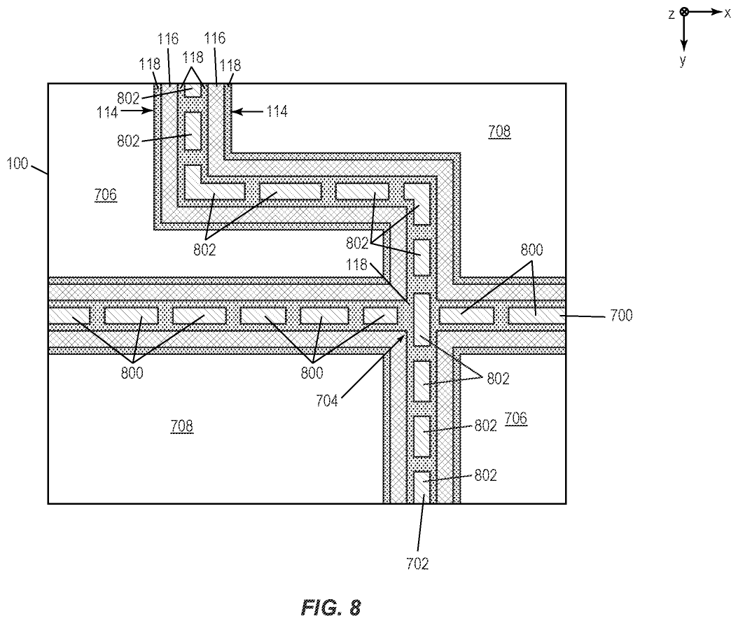

FIG. 8 illustrates a partial top plan view of the silicon layer 100, according to another embodiment. The embodiment illustrated in FIG. 8 is similar to the embodiment illustrated in FIG. 7. In FIG. 8, however, the first silicon mesa 700 is divided into of segments 800 that are separated from one another by the trench dielectric material 118 outside the area 704 where the first and second silicon mesas 700, 702 intersect one another. Separately or in combination, the second silicon mesa 702 may be divided into segments 802 that are separated from one another by the trench dielectric material 118 outside the area 704 where the first and second silicon mesas 700, 702 intersect one another.

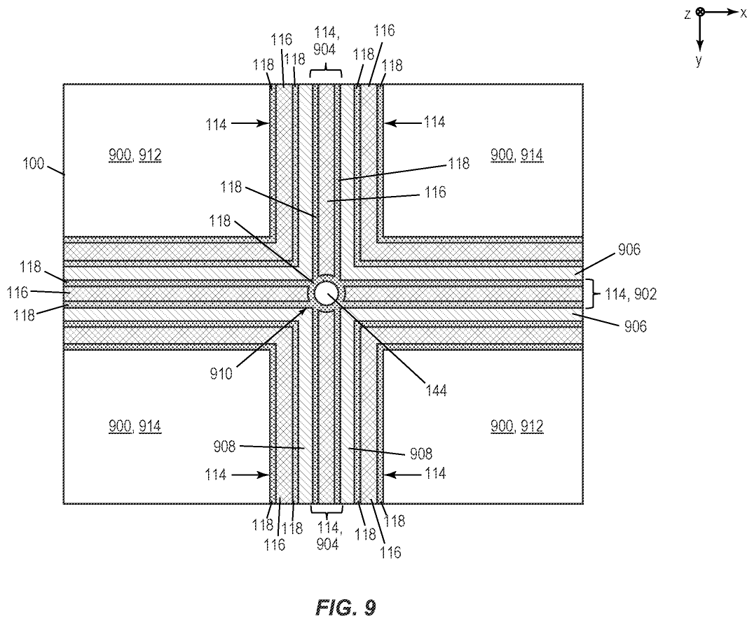

FIG. 9 illustrates a partial top plan view of the silicon layer 100, according to another embodiment. In FIG. 9, the device trenches 114 laterally isolate regions 900 of the silicon layer 100. A middle one 902 of the trenches 114 in a first lateral direction (x direction in FIG. 9) intersects a middle one 904 of the trenches 114 in a second lateral direction (y direction in FIG. 9) that is transverse to the first lateral direction. A silicon mesa 906 is between (delimited by) adjacent ones of the trenches 114 in the first lateral direction (x direction in FIG. 9). A silicon mesa 908 also is between (delimited by) adjacent ones of the trenches 114 in the second lateral direction (y direction in FIG. 9). A silicon plug 144 laterally surrounded by the trench dielectric material 118 interrupts the electrically conductive material 116 in the trenches 114 where the middle trench 902 in the first lateral direction (x direction in FIG. 9) intersects the middle trench 904 in the second lateral direction (y direction in FIG. 9).

In a lateral direction (x or y direction in FIG. 9), the average thickness of the trench dielectric material 118 around the silicon plug 144 may be greater than the average thickness of the trench dielectric material 118 between the laterally isolated regions 900 of the silicon layer 100 and the electrically conductive material 116 in the trenches 114. According to this embodiment, the silicon plug 144 is positioned within a mesa crossing 910 to yield a CD reduction and thus thicker dielectric material 118 at the mesa crossing 910.

In an embodiment, a first subset 912 of the laterally isolated regions 900 of the silicon layer 100 supports a first voltage domain and a second subset 914 of the laterally isolated regions 900 of the silicon layer 100 supports a second voltage domain different than the first voltage domain. According to this embodiment, the silicon plug 144 separates the electrically conductive material 116 in the middle trenches 902, 904 in the corner area 910 where one or more of the laterally isolated regions 912 of the first voltage domain adjoin one or more of the laterally isolated regions 914 of the second voltage domain.

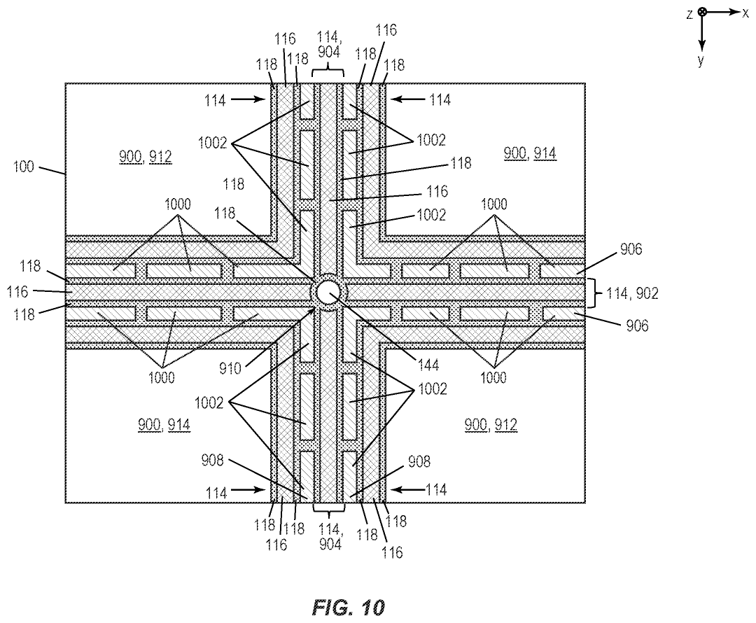

FIG. 10 illustrates a partial top plan view of the silicon layer 100, according to another embodiment. The embodiment illustrated in FIG. 10 is similar to the embodiment illustrated in FIG. 9. In FIG. 10, however, each silicon mesa 906 between adjacent ones of the trenches 114 in the first lateral direction (x direction in FIG. 10) is divided into segments 1000 that are separated from one another by the trench dielectric material 118. Separately or in combination, each silicon mesa 908 adjacent ones of the trenches 114 in the second lateral direction (y direction in FIG. 10) may be divided into segments 1002 that are separated from one another by the trench dielectric material 118.

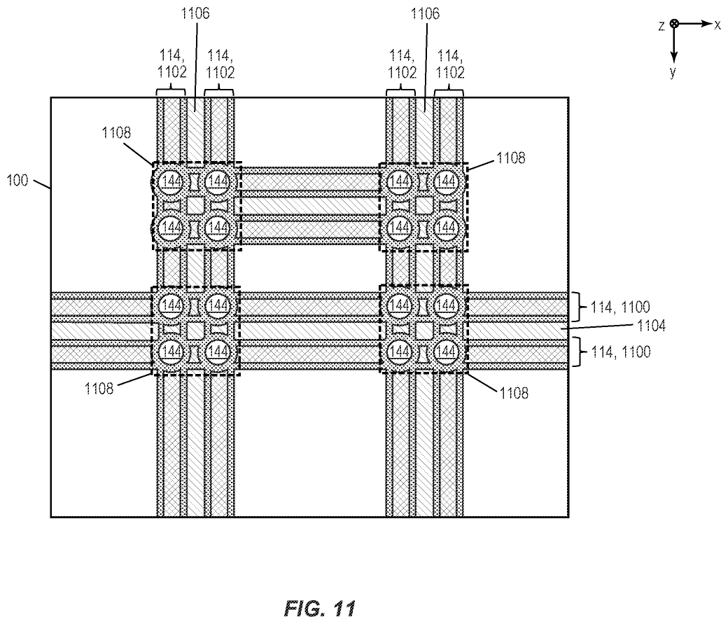

FIG. 11 illustrates a partial top plan view of the silicon layer 100, according to another embodiment. In FIG. 11, the semiconductor device has a first pair 1100 of the trenches 114 that segment the silicon layer 100 in a first lateral direction (x direction in FIG. 11) and a second pair 1102 of the trenches 114 that segment the silicon layer 100 in a second lateral direction (y direction in FIG. 11) that is transverse to the first lateral direction. A first silicon mesa 1104 is interposed between (delimited by) the trenches 114 of the first pair 1100 and a second silicon mesa 1106 is interposed between (delimited by) the trenches 114 of the second pair 1102. In each area 1108 where the first pair 1100 of trenches 114 and the second pair 1102 of trenches 112 intersect one another, silicon plugs 144 laterally surrounded by the trench dielectric material 118 divide the electrically conductive material 116 in the trenches 114 into separate segments 1110. Four (4) silicon plugs 144 are shown in each area 1108 where the first pair 1100 of trenches 114 and the second pair 1102 of trenches 112 intersect one another. In general, any number of silicon plugs 144 may be used to divide the electrically conductive material 116 in the trenches 114 into separate segments 1110 in each area 1108 where the first pair 1100 of trenches 114 and the second pair 1102 of trenches 112 intersect one another.

Although the present disclosure is not so limited, the following numbered examples demonstrate one or more aspects of the disclosure.

Example 1. A semiconductor device, comprising: a silicon layer having a frontside and an electrically insulated backside; a first trench extending through the silicon layer from the frontside to the electrically insulated backside and laterally isolating a first region of the silicon layer; an electrically conductive material in the first trench; a dielectric material separating the electrically conductive material from silicon material of the silicon layer; and a plurality of silicon plugs laterally surrounded by the dielectric material and dividing the electrically conductive material into a plurality of separate segments in the first trench.

Example 2. The semiconductor device of example 1, wherein in a lateral direction, an average thickness of the dielectric material around each silicon plug is greater than an average thickness of the dielectric material between the silicon material and the electrically conductive material.

Example 3. The semiconductor device of example 1 or 2, wherein the first region of the silicon layer includes a transistor device having a source region laterally separated from a drain region by a drift region, and wherein the silicon plugs divide the electrically conductive material into the separate segments between the source region and the drain region such that the separate segments are at different potentials when the transistor device is off.

Example 4. The semiconductor device of any of examples 1 through 3, further comprising: a second trench extending through the silicon layer from the frontside to the electrically insulated backside and laterally isolating a second region of the silicon layer, the second trench including the electrically conductive material, wherein the dielectric material separates the electrically conductive material in the second trench from the silicon material of the silicon layer, wherein the first and second trenches intersect or merge with one another, wherein one of the silicon plugs interrupts the electrically conductive material where the first and second trenches intersect or merge with one another.

Example 5. The semiconductor device of any of examples 1 through 4, wherein the first region of the silicon layer is laterally isolated from a second region of the silicon layer by the first trench, wherein the first and second regions support different voltage domains, and wherein at least one of the silicon plugs divides the electrically conductive material into at least two separate segments between the first and second regions of the silicon layer to form a capacitive coupler between the first and second regions.

Example 6. The semiconductor device of any of examples 1 through 5, wherein the plurality of silicon plugs interrupts the electrically conductive material at each location where the first trench merges with or intersects another trench that extends through the silicon layer from the frontside to the electrically insulated backside.

Example 7. The semiconductor device of any of examples 1 through 6, further comprising: a plurality of additional trenches extending through the silicon layer from the frontside to the electrically insulated backside and merging with the first trench, wherein the plurality of additional trenches laterally isolate a first additional region of the silicon layer from a second additional region of the silicon layer, wherein the first additional region supports a higher voltage domain than the second additional region, wherein a level shifter device is formed in the first region and configured to provide voltage level shifting between the first and second additional regions, wherein the plurality of silicon plugs interrupts the electrically conductive material where the plurality of additional trenches merge with the first trench.

Example 8. A semiconductor device, comprising: a silicon layer having a frontside and an electrically insulated backside; a plurality of trenches extending through the silicon layer from the frontside to the electrically insulated backside and laterally isolating a plurality of regions of the silicon layer; an electrically conductive material in trenches; a dielectric material separating the electrically conductive material from silicon material of the silicon layer; a first silicon mesa between adjacent ones of the trenches in a first lateral direction; a second silicon mesa between adjacent ones of the trenches in a second lateral direction that is transverse to the first lateral direction, wherein the first and second silicon mesas intersect one another; and in an area where the first and second silicon mesas intersect one another, a silicon plug or silicon mesa laterally surrounded by the dielectric material and separating the first and second silicon mesas from one another.

Example 9. The semiconductor device of example 8, wherein in a lateral direction, an average thickness of the dielectric material around the silicon plug is greater than an average thickness of the dielectric material between the silicon material and the electrically conductive material.

Example 10. The semiconductor device of example 8 or 9, wherein the first silicon mesa is divided into a plurality of segments separated from one another by the dielectric material outside the area where the first and second silicon mesas intersect one another.

Example 11. The semiconductor device of any of examples 8 through 10, wherein the second silicon mesa is divided into a plurality of segments separated from one another by the dielectric material outside the area where the first and second silicon mesas intersect one another.

Example 12. The semiconductor device of any of examples 8 through 11, wherein the first silicon mesa is divided into a plurality of segments separated from one another by the dielectric material outside the area where the first and second silicon mesas intersect one another, and wherein the second silicon mesa is divided into a plurality of segments separated from one another by the dielectric material outside the area where the first and second silicon mesas intersect one another.

Example 13. The semiconductor device of any of examples 8 through 12, wherein a first subset of the laterally isolated regions of the silicon layer supports a first voltage domain, wherein a second subset of the laterally isolated regions of the silicon layer supports a second voltage domain different than the first voltage domain, and wherein in a corner area where one or more of the laterally isolated regions of the first voltage domain adjoin one or more of the laterally isolated regions of the second voltage domain, the silicon plug separates the first and second silicon mesas from one another.

Example 14. A semiconductor device, comprising: a silicon layer having a frontside and an electrically insulated backside; a plurality of trenches extending through the silicon layer from the frontside to the electrically insulated backside and laterally isolating a plurality of regions of the silicon layer, wherein a middle one of the trenches in a first lateral direction intersects a middle one of the trenches in a second lateral direction that is transverse to the first lateral direction; an electrically conductive material in the trenches; a dielectric material separating the electrically conductive material from silicon material of the silicon layer; a silicon mesa between adjacent ones of the trenches in the first lateral direction and between adjacent ones of the trenches in the second lateral direction; and a silicon plug laterally surrounded by the dielectric material and interrupting the electrically conductive material where the middle trench in the first lateral direction intersects the middle trench in the second lateral direction.

Example 15. The semiconductor device of example 14, wherein in a lateral direction, an average thickness of the dielectric material around the silicon plug is greater than an average thickness of the dielectric material between the laterally isolated regions of the silicon layer and the electrically conductive material.

Example 16. The semiconductor device of example 14 or 15, wherein the silicon mesa between adjacent ones of the trenches in the first lateral direction is divided into a plurality of segments separated from one another by the dielectric material.

Example 17. The semiconductor device of any of examples 14 through 16, wherein the silicon mesa between adjacent ones of the trenches in the second lateral direction is divided into a plurality of segments separated from one another by the dielectric material.

Example 18. The semiconductor device of any of examples 14 through 17, wherein the silicon mesa between adjacent ones of the trenches in the first lateral direction is divided into a plurality of segments separated from one another by the dielectric material, and wherein the silicon mesa between adjacent ones of the trenches in the second lateral direction is divided into a plurality of segments separated from one another by the dielectric material.

Example 19. The semiconductor device of any of examples 14 through 18, wherein a first subset of the laterally isolated regions of the silicon layer supports a first voltage domain, wherein a second subset of the laterally isolated regions of the silicon layer supports a second voltage domain different than the first voltage domain, and wherein the silicon plug separates the electrically conductive material in the middle trenches in a corner area where one or more of the laterally isolated regions of the first voltage domain adjoin one or more of the laterally isolated regions of the second voltage domain.

Example 20. A semiconductor device, comprising: a silicon layer having a frontside and an electrically insulated backside; a first pair of trenches extending through the silicon layer from the frontside to the electrically insulated backside and segmenting the silicon layer in a first lateral direction; a second pair of trenches extending through the silicon layer from the frontside to the electrically insulated backside and segmenting the silicon layer in a second lateral direction that is transverse to the first lateral direction; an electrically conductive material in the first pair of trenches and the second pair of trenches; a dielectric material separating the electrically conductive material from silicon material of the silicon layer; a first silicon mesa interposed between the trenches of the first pair; a second silicon mesa interposed between the trenches of the second pair; and in an area where the first pair of trenches and the second pair of trenches intersect one another, a plurality of silicon plugs laterally surrounded by the dielectric material and dividing the electrically conductive material into a plurality of separate segments in the trenches.

Example 21. A method for manufacturing a semiconductor device, the method comprising: providing a silicon layer having a frontside and an electrically insulated backside; and forming a first trench structure that extends through the silicon layer from the frontside to the electrically insulated backside and that laterally isolates a first region of the silicon layer, wherein forming the first trench structure comprises: forming an electrically conductive material in the first trench; forming a dielectric material that separates the electrically conductive material from silicon material of the silicon layer; and forming a plurality of silicon plugs laterally surrounded by the dielectric material and that divide the electrically conductive material into a plurality of separate segments in the first trench.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to include all possible conjunctive and disjunctive combinations, unless expressly noted otherwise. For example, the expression “A and/or B” should be interpreted to mean only A, only B, or both A and B. The expression “at least one of” should be interpreted in the same manner as “and/or”, unless expressly noted otherwise. For example, the expression “at least one of A and B” should be interpreted to mean only A, only B, or both A and B.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor device, comprising:
a silicon layer having a frontside and an electrically insulated backside;
a first trench extending through the silicon layer from the frontside to the electrically insulated backside and laterally isolating a first region of the silicon layer;
an electrically conductive material in the first trench;
a dielectric material separating the electrically conductive material from silicon material of the silicon layer; and
a plurality of silicon plugs laterally surrounded by the dielectric material and dividing the electrically conductive material into a plurality of separate segments in the first trench.

2. The semiconductor device of claim 1, wherein in a lateral direction, an average thickness of the dielectric material around each silicon plug is greater than an average thickness of the dielectric material between the silicon material and the electrically conductive material.

3. The semiconductor device of claim 1, wherein the first region of the silicon layer includes a transistor device having a source region laterally separated from a drain region by a drift region, and wherein the silicon plugs divide the electrically conductive material into the separate segments between the source region and the drain region such that the separate segments are at different potentials when the transistor device is off.

4. The semiconductor device of claim 1, further comprising:
a second trench extending through the silicon layer from the frontside to the electrically insulated backside and laterally isolating a second region of the silicon layer, the second trench including the electrically conductive material,
wherein the dielectric material separates the electrically conductive material in the second trench from the silicon material of the silicon layer,
wherein the first and second trenches intersect or merge with one another,
wherein one of the silicon plugs interrupts the electrically conductive material where the first and second trenches intersect or merge with one another.

5. The semiconductor device of claim 1, wherein the first region of the silicon layer is laterally isolated from a second region of the silicon layer by the first trench, wherein the first and second regions support different voltage domains, and wherein at least one of the silicon plugs divides the electrically conductive material into at least two separate segments between the first and second regions of the silicon layer to form a capacitive coupler between the first and second regions.

6. The semiconductor device of claim 1, wherein the plurality of silicon plugs interrupts the electrically conductive material at each location where the first trench merges with or intersects another trench that extends through the silicon layer from the frontside to the electrically insulated backside.

7. The semiconductor device of claim 1, further comprising:
a plurality of additional trenches extending through the silicon layer from the frontside to the electrically insulated backside and merging with the first trench,
wherein the plurality of additional trenches laterally isolate a first additional region of the silicon layer from a second additional region of the silicon layer,
wherein the first additional region supports a higher voltage domain than the second additional region,
wherein a level shifter device is formed in the first region and configured to provide voltage level shifting between the first and second additional regions,
wherein the plurality of silicon plugs interrupts the electrically conductive material where the plurality of additional trenches merge with the first trench.

8. A semiconductor device, comprising:
a silicon layer having a frontside and an electrically insulated backside;
a plurality of trenches extending through the silicon layer from the frontside to the electrically insulated backside and laterally isolating a plurality of regions of the silicon layer;
an electrically conductive material in trenches;
a dielectric material separating the electrically conductive material from silicon material of the silicon layer;
a first silicon mesa between adjacent ones of the trenches in a first lateral direction;
a second silicon mesa between adjacent ones of the trenches in a second lateral direction that is transverse to the first lateral direction, wherein the first and second silicon mesas intersect one another; and
in an area where the first and second silicon mesas intersect one another, a silicon plug or silicon mesa laterally surrounded by the dielectric material and separating the first and second silicon mesas from one another.

9. The semiconductor device of claim 8, wherein in a lateral direction, an average thickness of the dielectric material around the silicon plug is greater than an average thickness of the dielectric material between the silicon material and the electrically conductive material.

10. The semiconductor device of claim 8, wherein the first silicon mesa is divided into a plurality of segments separated from one another by the dielectric material outside the area where the first and second silicon mesas intersect one another.

11. The semiconductor device of claim 8, wherein the first silicon mesa is divided into a plurality of segments separated from one another by the dielectric material outside the area where the first and second silicon mesas intersect one another, and wherein the second silicon mesa is divided into a plurality of segments separated from one another by the dielectric material outside the area where the first and second silicon mesas intersect one another.

12. The semiconductor device of claim 8, wherein a first subset of the laterally isolated regions of the silicon layer supports a first voltage domain, wherein a second subset of the laterally isolated regions of the silicon layer supports a second voltage domain different than the first voltage domain, and wherein in a corner area where one or more of the laterally isolated regions of the first voltage domain adjoin one or more of the laterally isolated regions of the second voltage domain, the silicon plug separates the first and second silicon mesas from one another.

13. A semiconductor device, comprising:
a silicon layer having a frontside and an electrically insulated backside;
a plurality of trenches extending through the silicon layer from the frontside to the electrically insulated backside and laterally isolating a plurality of regions of the silicon layer, wherein a middle one of the trenches in a first lateral direction intersects a middle one of the trenches in a second lateral direction that is transverse to the first lateral direction;
an electrically conductive material in the trenches;
a dielectric material separating the electrically conductive material from silicon material of the silicon layer;
a silicon mesa between adjacent ones of the trenches in the first lateral direction and between adjacent ones of the trenches in the second lateral direction; and
a silicon plug laterally surrounded by the dielectric material and interrupting the electrically conductive material where the middle trench in the first lateral direction intersects the middle trench in the second lateral direction.

14. The semiconductor device of claim 13, wherein in a lateral direction, an average thickness of the dielectric material around the silicon plug is greater than an average thickness of the dielectric material between the laterally isolated regions of the silicon layer and the electrically conductive material.

15. The semiconductor device of claim 13, wherein the silicon mesa between adjacent ones of the trenches in the first lateral direction is divided into a plurality of segments separated from one another by the dielectric material.

16. The semiconductor device of claim 13, wherein the silicon mesa between adjacent ones of the trenches in the second lateral direction is divided into a plurality of segments separated from one another by the dielectric material.

17. The semiconductor device of claim 13, wherein the silicon mesa between adjacent ones of the trenches in the first lateral direction is divided into a plurality of segments separated from one another by the dielectric material, and wherein the silicon mesa between adjacent ones of the trenches in the second lateral direction is divided into a plurality of segments separated from one another by the dielectric material.

18. The semiconductor device of claim 13, wherein a first subset of the laterally isolated regions of the silicon layer supports a first voltage domain, wherein a second subset of the laterally isolated regions of the silicon layer supports a second voltage domain different than the first voltage domain, and wherein the silicon plug separates the electrically conductive material in the middle trenches in a corner area where one or more of the laterally isolated regions of the first voltage domain adjoin one or more of the laterally isolated regions of the second voltage domain.

19. A semiconductor device, comprising:
a silicon layer having a frontside and an electrically insulated backside;
a first pair of trenches extending through the silicon layer from the frontside to the electrically insulated backside and segmenting the silicon layer in a first lateral direction;
a second pair of trenches extending through the silicon layer from the frontside to the electrically insulated backside and segmenting the silicon layer in a second lateral direction that is transverse to the first lateral direction;
an electrically conductive material in the first pair of trenches and the second pair of trenches;
a dielectric material separating the electrically conductive material from silicon material of the silicon layer;
a first silicon mesa interposed between the trenches of the first pair;
a second silicon mesa interposed between the trenches of the second pair; and
in an area where the first pair of trenches and the second pair of trenches intersect one another, a plurality of silicon plugs laterally surrounded by the dielectric material and dividing the electrically conductive material into a plurality of separate segments in the trenches.

20. A method for manufacturing a semiconductor device, the method comprising:
providing a silicon layer having a frontside and an electrically insulated backside; and
forming a first trench structure that extends through the silicon layer from the frontside to the electrically insulated backside and that laterally isolates a first region of the silicon layer,
wherein forming the first trench structure comprises:
forming an electrically conductive material in the first trench;
forming a dielectric material that separates the electrically conductive material from silicon material of the silicon layer; and
forming a plurality of silicon plugs laterally surrounded by the dielectric material and that divide the electrically conductive material into a plurality of separate segments in the first trench.
